(19) United States
(12) Patent Application Publication
(10) Pub. No.: US 2026/0114241 A1
(43) Pub. Date: Apr. 23, 2026

(54) METHOD OF PRE-ADJUSTING GLASS SUBSTRATE FOR MANUFACTURING GLASS SUBSTRATE SEMICONDUCTOR PACKAGE

(71) Applicant: Absolics Inc., Covington, GA (US)

(72) Inventors: Sangmin YUN, Covington, GA (US); YOUNJUNE KIM, Covington, GA (US)

(73) Assignee: Absolics Inc., Covington, GA (US)

(21) Appl. No.: 19/365,210

(22) Filed: Oct. 22, 2025

Related U.S. Application Data
(60) Provisional application No. 63/710,027, filed on Oct. 22, 2024.

(51) Int. Cl. H01L 21/66; H01L 21/67; H01L 21/677; H01L 21/68; H01L 23/15

(52) U.S. Cl. CPC H10P 74/23; H10P 72/0618; H10P 72/3212; H10W 70/692

(57) ABSTRACT

The present invention relates to a method of pre-adjusting a glass substrate for a glass substrate semiconductor package to significantly shorten manufacturing time and improve manufacturing efficiency includes selecting one material group from among a plurality of material groups, each of which has a plurality of glass substrates, collecting processing process information by a processing equipment for performing a processing process on the plurality of glass substrates belonging to the one material group according to identification codes, checking according to the processing process information, whether a transfer equipment associated with the processing equipment for performing a current processing process and a transfer equipment associated with the processing equipment for performing a next processing process are each provided with a flipper, and pre-adjusting each of the plurality of glass substrates by rotating the each of the plurality of plurality of glass substrates using the processing equipment for the current processing process.

### CROSS-REFERENCE TO RELATED APPLICATION

This application claims priority of U.S. Provisional Ser. No. 63/710,027 , filed on Oct. 22, 2024, the entire disclosure of which is hereby incorporated by reference for all purposes.

### BACKGROUND

### Technical Field

The present invention relates to a method of pre-adjusting a glass substrate for a glass substrate semiconductor package, which enables the glass substrate to be transferred to processing equipment after being pre-adjusted such that a current surface thereof corresponds to the working surface during processing of the glass substrate in a manufacturing process of the glass substrate semiconductor package.

### Related Art

Recently, in order to replace plastic substrates used in a semiconductor packaging field, glass substrates made of glass have been developed and are being used. Such glass substrates are regarded as innovative substrate materials that may change the landscape of the semiconductor packaging field.

That is, the glass substrate has a smooth surface and excellent processability into large quadrangular panels and is thus suitable for implementing semiconductor packaging with ultra-fine line widths. In addition, since no intermediate substrate is required, a thickness of the substrate can be reduced, and power consumption can also be reduced.

Meanwhile, unlike a plastic substrate that should be processed on a top surface and a bottom surface simultaneously, the glass substrate allows the top surface and the bottom surface to be individually processed according to material properties.

Due to these features, before processing the glass substrate to manufacture a glass substrate semiconductor package, a top-surface/bottom-surface adjustment operation should be performed in advance to rotate the glass substrate such that either the top surface of the glass substrate faces upward or the bottom surface faces upward depending on whether a working surface of the corresponding process is the top surface or the bottom surface of the glass substrate.

Here, manufacturing equipment for a glass substrate semiconductor package includes processing equipment that performs main processes of processing the glass substrate, and auxiliary equipment that assists the processing equipment and may rotate the glass substrate 180° to perform a top-surface/bottom-surface adjustment function.

The auxiliary equipment that performs the top-surface/bottom-surface adjustment function for a glass substrate includes a sorter and transfer equipment (e.g., an equipment front end module (EFEM)) optionally provided with the processing equipment. That is, the top-surface/bottom-surface adjustment function for a glass substrate is performed through a flip stage of the sorter and a flipper of transfer equipment.

However, only two to three sorters are installed in an entire semiconductor package manufacturing line, and not all transfer equipment is provided with flippers, but the flippers are selectively installed.

That is, when transfer equipment associated with processing equipment for a current process is not equipped with a flipper and an operation of rotating the glass substrate is required, the corresponding processing process is delayed, thereby reducing manufacturing efficiency.

Accordingly, in order to shorten process time and improve manufacturing efficiency, a process improvement technology is required that is capable of pre-adjusting a current surface of the glass substrate to correspond to the processing process using an available sorter and other transfer equipment equipped with a flipper and transferring the glass substrate to the corresponding processing equipment.

### SUMMARY

The present invention has been devised to solve the above-described problems, and an object thereof is to provide a method of pre-adjusting a glass substrate for a glass substrate semiconductor package, which enables the glass substrate to be transferred to processing equipment after being pre-adjusted such that a current surface thereof corresponds to a working surface for a processing process using an available sorter or other transfer equipment equipped with a flipper, thereby shortening process time and improving semiconductor package manufacturing efficiency.

The objectives of the present invention are not limited to the above-mentioned objective, and other objectives which are not mentioned above will be clearly understood from the following description and are sufficiently included in the objective of the present invention.

According to an aspect of the present invention, there is provided a method of pre-adjusting a glass substrate for manufacturing a glass substrate semiconductor package includes selecting one material group from among a plurality of material groups, each of which has a plurality of glass substrates that each have an identification code and are grouped and handled in one carrier, collecting processing process information by a processing equipment for performing a processing process on the plurality of glass substrates belonging to the one material group according to the identification codes, checking according to the processing process information, whether a transfer equipment associated with the processing equipment for performing a current processing process and a transfer equipment associated with the processing equipment for performing a next processing process, which is subsequent in order from the current processing process, are each provided with a flipper, and pre-adjusting each of the plurality of glass substrates by rotating the each of the plurality of plurality of glass substrates such that a current surface of each of the plurality of glass substrates corresponds to a working surface for a processing process; wherein the each of the plurality of glass substrates is pre-adjusted by rotating the each of the plurality of glass substrates using the processing equipment for the current processing process according to whether the current surface of the glass substrate matches the working surface and whether the working surface matches an unloading surface when the processing equipment for the current processing process and the processing equipment for the next processing process are each provided with the flipper; wherein the each of the plurality of glass substrates by rotating the each of the plurality of glass substrates using a sorter in an available state or other processing equipment in an available state and provided with the flipper when neither the processing equipment for the current processing process nor the processing equipment for the next processing process is provided with the flipper and the current surface of the glass substrate does not match the working surface.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a flowchart illustrating a method of pre-adjusting a glass substrate for a glass substrate semiconductor package according to an exemplary embodiment of the present invention; and

FIG. 2 is a configuration diagram illustrating a process management server for performing the method of pre-adjusting a glass substrate for a glass substrate semiconductor package according to the exemplary embodiment of the present invention.

### DETAILED DESCRIPTION

The present invention relates to a method of pre-adjusting a glass substrate for a glass substrate semiconductor package, in which the glass substrate used in the glass substrate semiconductor package is pre-adjusted such that a current surface thereof corresponds to a working surface for a processing process.

In particular, the method of pre-adjusting a glass substrate for a glass substrate semiconductor package in an embodiment of the present invention allows a pre-adjustment operation for the glass substrate to be quickly performed by pre-adjusting the glass substrate such that a current surface thereof corresponds to a working surface for a manufacturing process using a sorter capable of rotating the glass substrate and other transfer equipment equipped with a flipper when neither processing equipment for a current processing process nor processing equipment for a next processing process is provided with a flipper, thereby significantly improving manufacturing efficiency of the glass substrate semiconductor package.

Hereinafter, the method of pre-adjusting a glass substrate for a glass substrate semiconductor package in exemplary embodiments of the present invention will be described in detail with reference to the accompanying drawings.

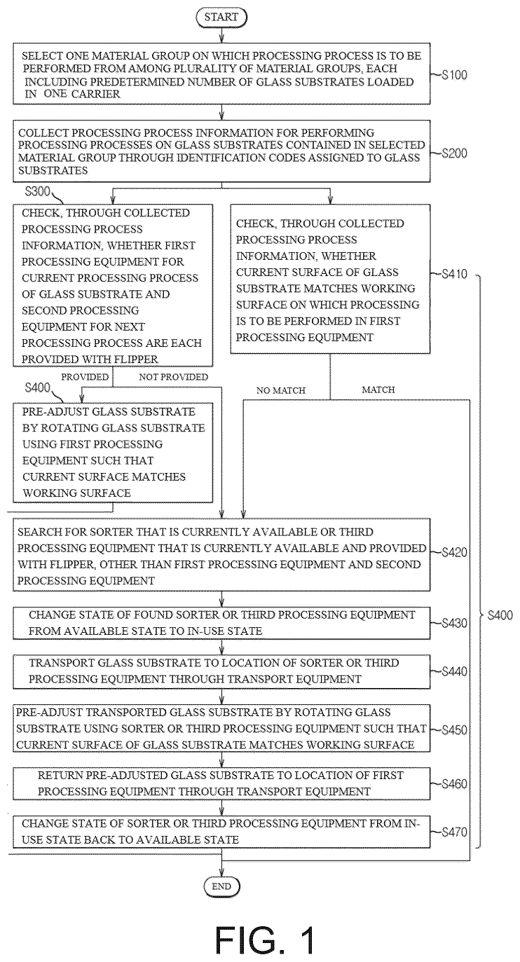

The method of pre-adjusting a glass substrate for a glass substrate semiconductor package in the exemplary embodiment of the present invention allows the glass substrate for manufacturing a glass substrate semiconductor package to be pre-adjusted such that the current surface thereof corresponds to the working surface for the current processing process, thereby shortening time for preparing to process the glass substrate, and, as illustrated in FIG. 1, may include a material group selection operation (S100), a processing process information collection operation (S200), a flipper check operation (S300), and a pre-adjustment operation (S400).

Here, the material group selection operation (S100), the processing process information collection operation (S200), the flipper check operation (S300), and the pre-adjustment operation (S400) may be performed by a process management server 100 that manages information on all processing processes of a glass substrate semiconductor package factory and controls all processing equipment of the glass substrate semiconductor package factory.

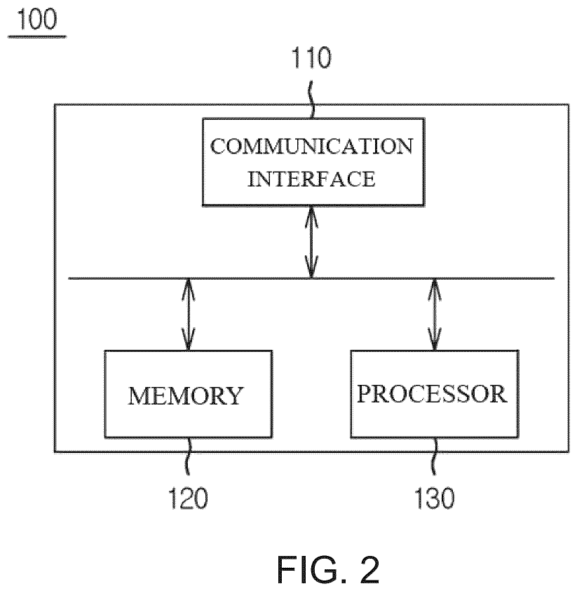

Meanwhile, as illustrated in FIG. 2, the process management server 100 may include a communication interface 110, a memory 120, and a processor 130, wherein the communication interface 110 performs communication with external electronic devices, receives a user input from the external electronic devices, or provides a data processing result to an administrator through an external terminal, the memory 120 includes a computer-readable recording medium and stores an operating system and preset instructions, and the processor 130 performs processing operations such as interpreting instructions and computing or comparing data.

First, in the material group selection operation (S100), one material group (Lot) on which a processing process is to be performed may be selected from among a plurality of material groups.

In this case, the material group may include a carrier (cassette) having a plurality of mounting slots installed therein and a plurality of glass substrates accommodated in the mounting slots of the carrier in a one-to-one correspondence.

In addition, each glass substrate may have a unique identification code to be distinguished from other glass substrates, and processing process information for each glass substrate may be obtained through the process management server using the identification code.

Next, in the processing process information collection operation (S200), the processing process information for performing processing processes on the plurality of glass substrates belonging to the material group selected in the material group selection operation (S100) may be collected using the identification codes possessed by the respective glass substrates.

That is, in the processing process information collection operation (S200), the processing process information for each of the glass substrates may be collected through the process management server by using the identification codes possessed by the respective glass substrates.

In this case, the processing process information may include process sequence information for the corresponding glass substrate, process equipment list information for processing the corresponding glass substrate according to the process sequence information, process equipment specification information for checking specifications of processing equipment included in the process equipment list information, and the like.

Next, in the flipper check operation (S300), based on the processing process information for the glass substrates collected in the processing process information collection operation (S200), it may be checked whether transfer equipment (e.g., an equipment front end module (EFEM)) associated with processing equipment performing a current processing process for the glass substrates and transfer equipment (e.g., EFEM) associated with processing equipment performing a next processing process, which is subsequent in order from the current processing process, are provided with flippers.

That is, in the flipper check operation (S300), it may be checked, through the process equipment specification information included in the processing process information, whether both first processing equipment for performing the current processing process for the glass substrates and second processing equipment for performing the next processing process are provided with flippers for changing the glass substrate such that the current surface corresponds to the working surface.

Finally, in the pre-adjustment operation (S400), based on whether a flipper is provided as confirmed in the flipper check operation (S300), the glass substrate may be pre-adjusted such that the current surface corresponds to the working surface by using the processing equipment for the current processing process, or by using a currently available sorter or other processing equipment located nearby.

That is, in the pre-adjustment operation (S400), when the transfer equipment associated with both the first processing equipment for the current processing process and the second processing equipment for the next processing process is provided with flippers, the glass substrate may be pre-adjusted using the corresponding flipper.

In addition, in the pre-adjustment operation (S400), when the transfer equipment associated with neither the first processing equipment nor the second processing equipment is provided with a flipper, a pre-adjustment operation for the glass substrate may be performed through a currently available sorter located nearby or through third processing equipment other than the first processing equipment and the second processing equipment, that is currently available and has transfer equipment provided with a flipper.

Here, the current surface is one surface of the glass substrate that faces upward in a state in which a carrier is placed on a port of transfer equipment before transferring the glass substrate accommodated in the carrier to processing equipment through the transfer equipment, the working surface is one surface of the glass substrate on which processing is performed in the processing equipment after transferring the glass substrate to the processing equipment through the transfer equipment, and an unloading surface may be one surface of the glass substrate that faces upward in a state in which the carrier is unloaded from the port of the transfer equipment after the processed glass substrate is accommodated in the carrier from the processing equipment.

That is, the top surface and the bottom surface of the glass substrate may each serve as the current surface, the working surface, or the unloading surface through a pre-adjustment operation in which the glass substrate is rotated 180°. This is because the glass substrate, unlike other conventional substrates, is capable of being individually processed by selecting at least one of the top surfaces and the bottom surface.

To this end, the pre-adjustment operation (S400), as illustrated in FIG. 1, may include a glass substrate current surface/working surface check operation (S410), an equipment search operation (S420), an equipment state change operation (S430), a glass substrate transport operation (S440), a glass substrate rotation operation (S450), an equipment state re-change operation (S460), and a glass substrate return operation (S470).

In the glass substrate current surface/working surface check operation (S410), it may be checked whether the current surface of the glass substrate matches the working surface on which a processing operation is to be performed by the first processing equipment for the current processing process.

In this case, in the glass substrate current surface/working surface check operation (S410), when the current surface of the glass substrate matches the working surface, the pre-adjustment operation for the glass substrate is not required, and therefore the glass substrate is loaded into the first processing equipment, and the pre-adjustment operation (S400) may be completed without performing subsequent detailed operations.

In the equipment search operation (S420), when the current surface of the glass substrate does not match the working surface in the glass substrate current surface/working surface check operation (S410), equipment that is currently available in the glass substrate semiconductor package factory and capable of rotating the glass substrate may be searched for to perform the pre-adjustment operation for the glass substrate.

That is, in the equipment search operation (S420), a sorter that is currently available in the glass substrate semiconductor package factory or the third processing equipment that is currently available and provided with a flipper may be searched for.

In the equipment state change operation (S430), when the sorter that is currently available or the third processing equipment that is currently available and provided with a flipper is found in the equipment search operation (S420), a state of the corresponding equipment may be changed from an available state to an in-use state in order to use the corresponding equipment.

In the glass substrate transport operation (S440), the carrier accommodating the corresponding glass substrate may be transported, through transport equipment provided in the glass substrate semiconductor package factory, to a location of the sorter or the third processing equipment whose state has been changed to the in-use state in the equipment state change operation (S430).

In the glass substrate rotation operation (S450), after the glass substrate is withdrawn from the carrier transported to the location of the sorter or the third processing equipment in the glass substrate transport operation (S440), the glass substrate may be rotated 180° using the sorter or the third processing equipment so that the current surface of the glass substrate matches the working surface, and then the glass substrate may be loaded back into the carrier.

In the equipment state re-change operation (S460), after the pre-adjustment operation for the corresponding glass substrate is completed, the state of the corresponding equipment may be changed from the in-use state back to the available state so that the corresponding equipment can be used for another purpose.

In the glass substrate return operation (S470), the glass substrate, whose current surface has been rotated to match the working surface in the glass substrate rotation operation (S450), may be returned to a location of the first processing equipment through transport equipment provided in the glass substrate semiconductor package factory.

According to the configuration described above, a method of pre-adjusting a glass substrate for a glass substrate semiconductor package in an embodiment of the present invention enables a pre-adjustment operation for the glass substrate to be quickly performed, even when neither processing equipment for a current processing process nor processing equipment for a next processing process is provided with a flipper and a current surface of the glass substrate does not match the working surface, by searching for a currently available sorter or other processing equipment and using the same to pre-adjust the glass substrate such that the current surface matches the working surface, thereby shortening a time required for manufacturing the glass substrate semiconductor package and improving manufacturing efficiency.

The above-described embodiments are merely exemplary, and various other embodiments modified therefrom may be implemented by those skilled in the art.

Accordingly, the true technical scope of the present invention should be construed as including not only the embodiments but also various other embodiments modified based on the technical spirit of the invention described in the following claims.

What is claimed is:

1. A method of pre-adjusting a glass substrate for manufacturing a glass substrate semiconductor package, the method comprising:
selecting one material group from among a plurality of material groups, each of which has a plurality of glass substrates that each have an identification code and are grouped and handled in one carrier;
collecting processing process information by a processing equipment for performing a processing process on the plurality of glass substrates belonging to the one material group according to identification codes;
checking according to the processing process information, whether a transfer equipment associated with the processing equipment for performing a current processing process and a transfer equipment associated with the processing equipment for performing a next processing process, which is subsequent in order from the current processing process, are each provided with a flipper; and
pre-adjusting each of the plurality of glass substrates by rotating the each of the plurality of plurality of glass substrates such that a current surface of each of the plurality of glass substrates corresponds to a working surface for a processing process;
wherein the each of the plurality of glass substrates is pre-adjusted by rotating the each of the plurality of glass substrates using the processing equipment for the current processing process according to whether the current surface of the glass substrate matches the working surface of the current processing process and whether the working surface of the next processing process matches an unloading surface when the processing equipment for the current processing process and the processing equipment for the next processing process are each provided with the flipper;
wherein the each of the plurality of glass substrates is pre-adjusted by rotating the each of the plurality of glass substrates using a sorter in an available state or other processing equipment in an available state and provided with the flipper when neither the processing equipment for the current processing process nor the processing equipment for the next processing process is provided with the flipper and the current surface of the glass substrate does not match the working surface of the next processing process.

2. The method of claim 1, wherein the pre-adjusting comprises:
determining, based on the processing process information, whether the current surface of the glass substrate matches the working surface when the processing equipment for the current processing process and the processing equipment for the next processing process are provided with the flipper and the current surface of the glass substrate does not match the working surface; and
rotating the glass substrate using the processing equipment for the current processing process so that the current surface of the glass substrate matches the working surface when the current surface of the glass substrate does not match the working surface based on a result of the determining of whether the current surface matches the working surface.

3. The method of claim 1, wherein the pre-adjusting comprises:
determining, based on the processing process information, whether the current surface of the glass substrate matches the working surface, when neither the processing equipment for the current processing process nor the processing equipment for the next processing process is provided with the flipper and the current surface of the glass substrate does not match the working surface;
searching for the sorter in the available state or the other processing equipment in the available state and provided with the flipper, when the current surface of the glass substrate does not match the working surface based on a result of the determining of whether the current surface matches the working surface; and
rotating the glass substrate using a found sorter or the other processing equipment so that the current surface of the glass substrate matches the working surface.

4. The method of claim 3, wherein the rotating the each of the plurality of glass substrates comprises:
transporting the glass substrate to the found sorter;
matching the current surface of the glass substrate with the working surface by rotating the glass substrate using the sorter; and
returning the glass substrate with the current surface matched to the working surface to the processing equipment for the current processing process.

5. The method of claim 4, wherein the rotating the each of the plurality of glass substrates comprises, before the transporting the glass substrate, changing a state of the sorter from the available state to an in-use state when the sorter is found based on a result of the searching, and
wherein the method further comprises changing the state of the sorter from the in-use state to the available state between the matching of the current surface and the returning of the glass substrate to the processing equipment.

6. The method of claim 3, wherein the rotating the each of the plurality of glass substrates comprises:
transporting the glass substrate to the found other processing equipment;
matching the current surface of the glass substrate with the working surface by rotating the glass substrate using the other processing equipment; and
returning the glass substrate, which is pre-adjusted such that the current surface matches the working surface, to the processing equipment for the current processing process.

7. The method of claim 6, wherein the matching the current surface of the glass substrate comprises:
before the transporting the glass substrate, changing a state of the other processing equipment from the available state to an in-use state when the other processing equipment is found based on a result of the searching; and
wherein the method further comprises changing the state of the other processing equipment from the in-use state to the available state during the matching of the current surface and the returning of the glass substrate to the processing equipment.
